(19) United States
(12) Patent Application Publication
(10) Pub. No.: US 2009/0141218 A1
(43) Pub. Date: Jun. 4, 2009

(54) METHODS AND APPARATUS FOR CURING PIXEL MATRIX FILTER MATERIALS

(75) Inventors: Ligui Zhou, Dublin, CA (US); Quanyuan Shang, Saratoga, CA (US)

Correspondence Address: DUGAN & DUGAN, PC, 245 Saw Mill River Road, Suite 309, Hawthorne, NY, 10532, US

(73) Assignee: APPLIED MATERIALS, INC., Santa Clara, CA (US)

(21) Appl. No.: 12/257,380

(22) Filed: Oct. 23, 2008

Related U.S. Application Data
(60) Provisional application No. 60/983,137, filed on Oct. 26, 2007.

(51) Int. Cl. G02F 1/1335; G03F 1/00

(52) U.S. Cl. 349/106; 430/7

(57) ABSTRACT

In the formation of color filters for flat panel displays, the invention includes concurrently curing and shrinking a pixel matrix and a color material on a substrate to achieve a substantially co-planar top surface. The invention includes applying a first activation energy to a pixel matrix material to render the material partially cured, minimally shrunk, hardened, and chemically ready for the application of a color material; applying the color material; and concurrently shrinking the color material and pixel material by the application of at least an additional activation energy wherein the additional activation energy is greater than the first activation energy. Numerous other aspects are provided.

The present application claims priority to U.S. Provisional Patent Application No. 60/983,137 filed Oct. 26, 2007, and entitled “METHODS AND APPARATUS FOR CURING PIXEL MATRIX FILTER MATERIALS” (Attorney Docket No. 12006/L) which is hereby incorporated herein by reference in its entirety for all purposes.

### CROSS-REFERENCE TO RELATED APPLICATIONS

The present application is related to the following commonly-assigned, co-pending U.S. patent applications, each of which is hereby incorporated herein by reference in its entirety for all purposes:

U.S. patent U.S. patent application Ser. No. 11/733,665, Attorney Docket No. 11292 Display/inkjet filed on Apr. 10, 2007 entitled “Black Matrix Compositions and Methods of Forming the Same”

U.S. patent application Ser. No. 11/536,540, Attorney Docket No. 10448/Display/inkjet filed on Sep. 28, 2006 entitled “Methods and Apparatus for Adjusting Pixel Fill Profiles”

U.S. patent application Ser. No. 11/521,577, Attorney Docket No. 10502/Display/AKT/RKK, filed on Sep. 13, 2006, entitled “Method and Apparatus For Manufacturing a Pixel Matrix of a Color Filter for a Flat Panel Display”

U.S. patent application Ser. No. 11/737,141 Attorney Docket No. 11548/Display/inkjet/RKK filed on Apr. 19, 2007 entitled “Methods and Apparatus for Inkjetting Spacers in a Flat Panel Display”

### FIELD OF THE INVENTION

The present invention relates to the manufacture of color filters for flat panel displays, and more particularly to methods of pixel matrix and color material integration into the color filter of a flat panel display.

### BACKGROUND OF THE INVENTION

The flat panel display manufacturing industry has been attempting to employ inkjet printing to construct display device components, in particular, color filters. In the manufacture of color filters, a printer may be used to deposit color material into pixel wells of a matrix formed on a substrate. One problem with effective employment of inkjet printing is that it is often difficult to achieve a planar surface at the top of the color material and pixel matrix material on the color filter substrate. Additionally, gaps may exist between the color material and the pixel matrix material. The lack of a co-planar surface or the presence of gaps requires the use of a leveling/filling material which adds additional cost and time to the manufacturing process. What is needed is a method to improve the quality of color filter apparatus manufactured using high throughput inkjet printing.

### SUMMARY OF THE INVENTION

In an aspect of the invention, a method of processing a substrate is provided. The method includes applying a first activation energy to a patterned pixel matrix material on a substrate sufficient to cause the patterned pixel matrix material to attain a first state, wherein the patterned pixel matrix material in the first state includes a minimized change in volume relative to a volume of the patterned pixel matrix material prior to application of the first activation energy and an increased hardness sufficient to withstand inkjetting; inkjetting a color material onto the substrate; and applying an additional activation energy to the patterned pixel matrix material sufficient to attain a second state, wherein the patterned pixel matrix material in the second state includes a reduction in the volume of the patterned pixel matrix material and is substantially hardened.

In another aspect of the invention, a method of processing a substrate is provided. The method includes applying a first activation energy to a patterned pixel matrix material on a substrate sufficient to cause the patterned pixel matrix material to attain a first state, wherein the patterned pixel matrix material in the first state is adapted to withstand inkjetting; inkjetting a color material onto the substrate; and applying an additional activation energy to the patterned pixel matrix material sufficient to attain a second state, wherein concurrent shrinking of the patterned pixel matrix material and the color material results in a top surface of the patterned pixel matrix material and a top surface of the color material being approximately co-planar.

In yet another aspect of the invention, an apparatus is provided including a substrate; a patterned pixel matrix material with a top surface, the patterned pixel matrix material formed on the substrate; and a color material with a top surface, the color material deposited into the patterned pixel matrix material. The patterned pixel matrix material and the color material are cured such that concurrent shrinking of the patterned pixel matrix material and the color material results in the top surface of the patterned pixel matrix material and the top surface of the color material being approximately co-planar.

In still yet another aspect of the invention, an apparatus is provided including a patterned pixel matrix material with a top surface; and a color material with a top surface. The top surface of the patterned pixel matrix material and the top surface of the color material are approximately co-planar. A first activation energy is applied to the patterned pixel matrix prior to an application of the color material. An additional activation energy is applied concurrently to the patterned pixel matrix material and the color material. The first application energy is less than the additional activation energy.

In other aspects of the invention, a system is provided including a first substrate with a transistor array; a second substrate having a patterned pixel matrix material with at least one top surface and a color material with at least one top surface wherein the at least one top surface of the patterned pixel matrix material and the at least one top surface of the color material are approximately co-planar; a sealant for assembling the first substrate and the second substrate; a spacer separating the first substrate and the second substrate; a liquid crystal material between the first substrate and the second substrate; and one or more polarizers adhered to the outside of the first substrate and the second substrate.

Other features and aspects of the present invention will become more fully apparent from the following detailed description, the appended claims and the accompanying drawings.

### BRIEF DESCRIPTION OF THE DRAWINGS

FIG. 1 is a flow chart depicting an example method in accordance with some aspects of the present invention.

FIGS. 2a-2d are magnified, cross-sectional schematic views of a portion of an example substrate with a patterned pixel matrix material according to some aspects of the present invention.

FIG. 3 is a magnified, cross-sectional schematic view of a portion of an example TFT-LCD color panel illustrating some aspects of the present invention.

### DETAILED DESCRIPTION

Thin film transistor liquid crystal displays (TFT-LCDs) include two glass substrates which sandwich the liquid crystals. One glass substrate, referred to as the TFT substrate includes the thin film transistors, storage capacitors, pixel electrodes and interconnect wiring. The second substrate referred to as the color-filter substrate contains the pixel matrix (also sometimes referred to as the black matrix) and resin film containing, typically, three primary colors (for example red, green and blue). The red, green, blue (RGB) portion of the color filters can be made with inks, dyes pigments or similar materials and are applied to the substrate by either dyeing, diffusing, electro-depositing or printing (including inkjet printing). The inks, dyes, pigments or similar materials which make up the RGB portion of the color filter, will be referred to as color material for the purposes of this invention.

Between the blocks of color material in the color filter is the pixel matrix. One function of the pixel matrix may be to shield the TFTs from stray light and prevent light leakage between pixels. The pixel matrix may be made from a variety of materials including opaque metals, sometimes in combination with their oxides. In addition, the pixel matrix may be made from polymeric resins such as photoresists. Often the photoresists are diffused with carbon and titanium to further reduce reflectivity. Additional pixel matrix compositions are disclosed below.

Before the color material is deposited, pixel wells may be formed on the substrate using lithography or any suitable process to pattern the pixel matrix material. Additionally, the pixel matrix material is cured, typically by UV exposure or heating, so that the material can withstand the chemical and physical forces of inkjetting. The curing process causes the pixel matrix material to partially shrink. After the color material is deposited, differences in the thermal expansion properties of the pixel matrix material, which has already undergone one cure (thermal) cycle, and the color material cause the materials to shrink at different rates or by different amounts during subsequent heating or curing step(s). The consequence of the curing sequence and different shrinking rates of the materials is that the level of the color material inside the pixel well may not be at the desired level relative to the top surface of the pixel matrix material (e.g., the top surfaces of the materials may not be coplanar, e.g., to within approximately 0.2 μm or less). In addition, different shrinking rates may also result in gaps forming along the interface of the side of the patterned pixel matrix pixel well and the side of the color material. In order to cover the gaps or level the top surface of the patterned pixel matrix material and the top surface of the color material, a leveling/filling agent can be applied. A leveling/filling agent is undesirable because it adds additional process complexity and cost.

The present invention provides methods and apparatus for adjusting or controlling the shrinking rates of the patterned pixel matrix material of the pixel wells and the color material so that concurrent shrinking of the materials occurs resulting in a substantially co-planar top surface of the pixel matrix and color materials without gaps (e.g., coplanar to within approximately 0.2 μm or less). In some embodiments, concurrent shrinking may be achieved by submitting the pixel matrix to a first cure which renders the matrix material sufficiently hardened to withstand the inkjetting process and chemically ready to receive the color material without substantially shrinking the patterned pixel matrix material. Thereafter, a color material is applied so that the color material and pixel matrix materials may concurrently undergo a subsequent curing step or steps. The subsequent curing step(s) concurrently shrink(s) the color material and the pixel matrix material. Curing the material in this manner may avoid creating gaps between the pixel matrix and color materials. The resulting structure may be used to eliminate the need of a leveling/filling agent.

In some processes of making color filters for flat panel displays, pixel wells are defined by lithographically (or any other suitable process) patterning the pixel matrix material. Very often after patterning a polymeric based pixel matrix material, a variety of baking (heating) or curing steps take place. Curing refers to the toughening or hardening of a polymer material which may occur by cross-linking of polymer chains. The curing may be brought about by methods including exposure to heat, ultraviolet radiation, electron beam (EB) radiation, infrared radiation, or laser light radiation. In addition, additives may be added to the pixel matrix material to facilitate or enhance curing. Regardless of the method used to initiate the cross-linking, or later solvent removal, the methods may each involve the application of an activation energy to the material(s). Therefore, for the purposes of the description of the present invention, curing including, but not limited to, heating, baking, electron beam, ultraviolet radiation, infrared radiation, or laser exposure may be thought as applying an activation energy and vice versa.

A typical, conventional process flow for the manufacture of a color filter for a flat panel display may involve patterning the pixel matrix material, “hard baking” the patterned pixel matrix material, applying the color material, “soft baking” and then “hard baking” the substrate with both the pixel matrix material and the color material. A “hard bake” typically occurs at temperatures greater than or equal to approximately 200 C for about 10 minutes and may completely cure the material. A “soft bake” typically occurs at temperatures less than or about 110 C, preferably between approximately 80 C and approximately 105 C and occurs for less than about 10 minutes and may only partially cure the material. Alternatively, ultraviolet (UV) radiation may be used to impart activation energy as well as other techniques. If a UV cure is used, the duration may typically be approximately 30 to approximately 60 seconds to achieve a ‘soft bake’ activation energy and up to approximately 10 minutes to achieve a ‘hard bake’ activation energy. As stated earlier, the purpose of applying the hard and soft bake activation energies may be to promote cross-linking (predominantly via the hard bake) in the pixel matrix material and to remove solvents. The cross-linking occurring during the first hard bake not only helps to make the pixel matrix material harder and therefore less likely to mix with the color material and to retain its form during the inkjetting process, but also helps to make the pixel matrix material chemically ready for the application of the color material. Chemically ready may mean that the top surface of the pixel matrix surface has been made “phobic” to the color material thereby dissuading the color material from staying on the top surface of the pixel matrix material and, instead, tending to fall into the pixel wells. It is desirable that the top surface of the pixel matrix material be free of color material in order to have a high quality color filter, particularly with respect to contrast ratio. U.S. patent application Ser. No. 11/733,665, Attorney Docket No. 11292 Display/inkjet filed on Apr. 10, 2007 entitled “Black Matrix Compositions and Methods of Forming the Same” provides details regarding the “phobicity” or “philicity” of pixel matrix materials with respect to color materials and process conditions and is incorporated herein by reference in its entirety for all purposes. In one aspect of the cited application, the pixel matrix material contains an additive with polymerizable molecules, the polymerizable molecules may include polar portions and non-polar portions. The non-polar portions are ink-phobic and migrate toward the surface of the pixel matrix composition upon the surface being exposed to an activation energy. The polar portions of the polymerizable molecules are ink-philic relative to the non-polar portions. The result when used to form a pixel matrix is a structure having an ink-phobic top surface and ink-philic sidewall surfaces. Ink-philic sidewalls may be one of the important factors to help prevent gap formation at the interface of the pixel well sidewall and the color material. In another commonly assigned patent application, U.S. patent application Ser. No. 11/521,577, a similar structure is achieved by making the sidewalls of an otherwise ink-phobic material ink-philic through exposing the sidewalls to laser ablation. U.S. patent application Ser. No. 11/521,577, Attorney Docket No. 10502/Display/AKT/RKK, filed on Sep. 13, 2006, and entitled “Method and Apparatus For Manufacturing a Pixel Matrix of a Color Filter for a Flat Panel Display” is incorporated herein by reference in its entirety for all purposes.

One of the problems with the above described steps is that throughout the various baking or curing (activation energy) processes, the pixel matrix material and color material will shrink at different rates during the different steps of the process. For example, only the pixel matrix material is exposed to the first hard bake. During the first hard bake, the polymer based pixel matrix material shrinks. After the color material has been printed (deposited into the cured pixel matrix), both the color material and the pixel matrix undergo soft and hard bakes. Since this is the first time that the color material has experienced a heat treatment (or alternate activation energy treatment), the color material may shrink at a faster rate than the matrix material which may not shrink at all. The end result is that, even though the color material and the matrix material started at the same level, the top surface of the color material may become substantially lower than the top surface of the pixel matrix material. In order to level the step height difference in the pixel matrix and ink surfaces, a leveling coat is added.

To eliminate the need for a leveling coat, the present invention replaces the first hard bake (the bake prior to color material deposition), with a medium bake which only initiates but does not complete cross-linking, initiates solvent removal, and only minimally shrinks the patterned pixel matrix material. However, the medium bake is still sufficient to render the pixel matrix material chemically ready for the application of the color material and physically able to withstand the inkjetting process. Chemically ready, as described earlier, may include allowing the polar and non-polar portions of an additive in the pixel matrix material to orient so that the top surface of the pixel matrix material is “ink-phobic” and the sidewalls of the patterned pixel matrix material are relatively “ink-philic”. Under this scenario, a medium bake (or analogous conditions for the other techniques such as UV cure, electron beam exposure, laser exposure, etc.) becomes the first activation energy of the process.

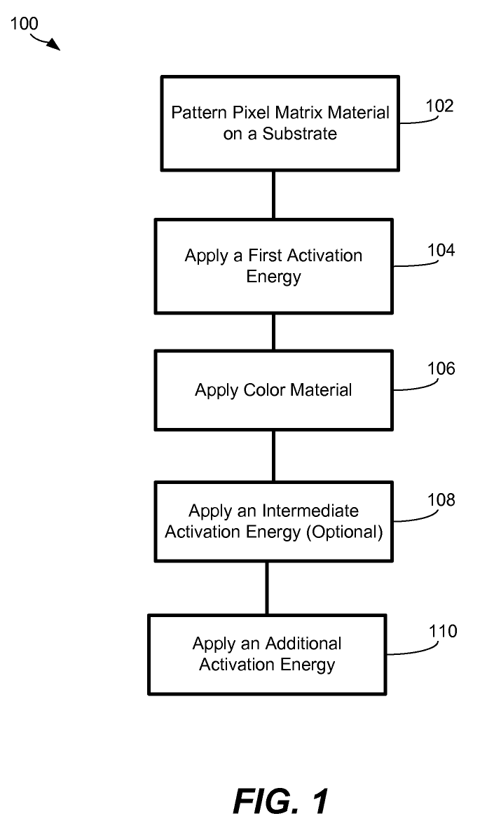

FIG. 1 depicts a flow chart of the steps of a proposed process 100 in detail. In step 102, a patterned pixel matrix material is provided on a substrate. In step 104, the patterned pixel matrix material and substrate are treated to a first activation energy. The first activation energy may be a medium bake at a temperature between approximately 120° C. and approximately 200° C., preferably between approximately 160° C. and approximately 200° C. for a period of approximately 5 minutes or less. Note that other times and temperatures may be used to achieve the stated functional results. Similarly, analogous conditions could be used for other activation techniques. Next, in step 106, a color material may be added to the pixel well formed by the patterned pixel matrix. In step 108, a second exposure to activation energy is applied to the substrate. Although this application is the second activation energy to which the patterned pixel matrix is exposed, this application is the first activation energy shared by both the pixel matrix and color materials. The activation energy may be a soft bake which typically occurs at temperatures of less than or about 110° C., preferably between approximately 80° C. and approximately 105° C. and occurs for approximately 10 minutes or less. The soft bake or analogous conditions for the other activation energy techniques, constitutes an intermediate activation energy to which the substrate is exposed. In some embodiments, the soft bake/intermediate activation energy application may be skipped. In step 110, an additional activation energy, shared by the pixel matrix and color material, is applied. The additional activation energy may be a hard bake at temperatures greater than or about 200° C. for about 10 minutes. As indicated above, the activation energy steps may be carried out by a variety of means including but not limited to application of UV radiation, electron beam radiation, IR radiation, laser light, and rapid thermal processing. In addition, the activation energies may occur in a variety of ambient conditions, including but not limited to vacuum, air, nitrogen, and argon.

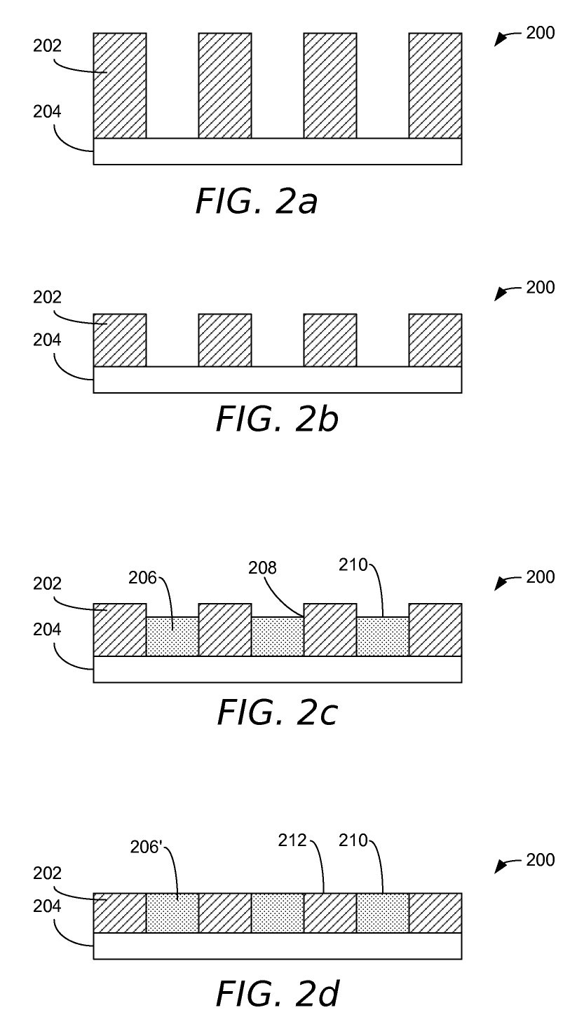

FIGS. 2a through 2d illustrate a color filter 200 being processed by the method 100 depicted in FIG. 1. FIG. 2a begins with a patterned pixel matrix material 202 provided on a substrate 204. The substrate 204 may include glass, triacetylcellulose (TAC), polycarbonate (PC), polyethersulfone (PES), polyethylenetherephtalate (PET), polyethylenenaphthalate (PEN), polyvinylalcohol (PVC), polymetylmethacrylate (PMMA), cyclo-olefin polymer (COP) and/or another suitable material. The pixel matrix material composition may include a pigment dispersion additive, an initiator, a polymerizable monomer or oligomer or combination thereof (e.g., a photo-polymerizable monomer, thermal-polymerizable monomer, etc.), a binder resin, an epoxy-based monomer, a solvent and a wetting additive. Additional details regarding possible pixel matrix materials and methods of applying the material are given in previously incorporated U.S. patent application Ser. No. 11/733,665, Attorney Docket No. 11292, filed on Apr. 10, 2007 entitled “Black Matrix Compositions and Methods of Forming the Same”

A blanket pixel matrix material may be formed on the substrate 204 using an immersing method, a spraying method, a rotating and spin-coating method or another suitable to form a coating. The blanket material is then patterned using well known lithographic methods, consequently, to form the patterned pixel matrix material 202 on the substrate 204

FIG. 2b depicts the substrate 204 and patterned pixel matrix 202′ after the medium bake heat treatment/fist activation energy. Though the figure is not to scale, the height of the patterned pixel matrix material is shown to be minimally reduced due to shrinking from the medium bake. Over the course of the at least two temperatures/activation energies to which the substrate will be exposed, the pixel matrix will shrink to a final height. In some embodiments, less than half of the total shrinking that occurs to the patterned pixel matrix height may occur due to the heating at a first temperature/activation energy.

FIG. 2c depicts the substrate 204, patterned pixel matrix material 202′ and the “as deposited” color material 206. As enumerated earlier, there are multiple color material choices and methods of depositing the materials. A preferred color material and method of deposition is ink (e.g., pigment dissolved in solvent) by inkjet printing. Depending upon the quantity of color material 206 deposited and the surface energy differences between the color material 206 and the side wall surface 208 of the pixel matrix material 202, the top surface 210 of the color material 206 may be either flat, concave or convex as explained in previously incorporated U.S. patent application Ser. No. 11/733,665, Attorney Docket No. 11292 filed on Apr. 10, 2007, entitled “Black Matrix Compositions and Methods of Forming the Same”. In order to compensate for the differences in surface energies of the color material and the pixel matrix material, a modified inkjetting process is described in U.S. patent application Ser. No. 11/536,540, Attorney Docket No. 10448 filed on Sep. 28, 2006 entitled “Methods and Apparatus for Adjusting Pixel Fill Profiles” which is incorporated herein by reference in its entirety for all purposes. For the sake of simplicity, the surface of the color material in FIG. 2c is shown as flat, but could be convex or concave as explained in the above patent applications. In addition, the height of the deposited color material 206 may be higher, level with, or lower (as shown) than the pixel matrix material 202. For example, the color material 206 may have a convex top surface that is higher than the level of the top surface of the pixel matrix material 202.

FIG. 2d depicts the color filter 200 after the remainder of the process steps have been completed, specifically, the optional soft bake or intermediate activation energy (step 108 of FIG. 1) and the hard bake or additional activation energy (step 110 of FIG. 1). During these last step(s), the patterned pixel matrix material and color material concurrently shrink. Hence the pixel matrix material is now labeled 202″ to indicate that further height reduction has occurred, likewise the color material has been labeled 206′. After the shared heating steps (application of activation energies), the top surface of the patterned pixel matrix material 212 and the top surface of the color material 210 are approximately co-planar save the minor perturbations (either convex or concave) at the intersection of the top surface of the color material and side walls of the pattern pixel matrix material pixel well. At this point, the level of the top surface of the color material and the top surface of the pixel matrix material may be sufficiently aligned as to negate the need to use of a leveling agent. Additionally, gaps at the interface of the side walls of the patterned pixel matrix material and the color material may not be present, further negating the need for a leveling/filling agent.

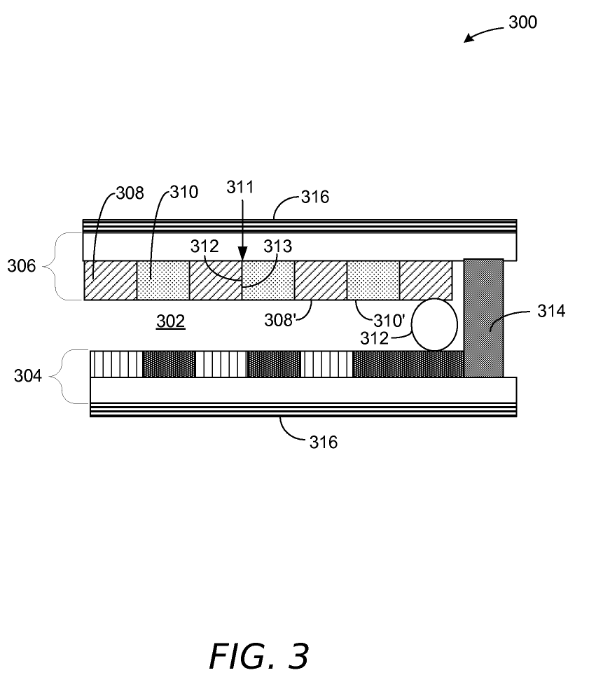

FIG. 3 illustrates the color filter described in FIG. 2 made by the methods of FIG. 1 installed in a flat panel display system 300. Referring to FIG. 3, a thin film transistor liquid crystal display (TFT-LCDs) 300 may be constructed of two glass substrates which sandwich liquid crystals 302. One glass substrate, referred to as the TFT substrate 304 includes the thin film transistors, storage capacitors, pixel electrodes and interconnect wiring. The second substrate referred to as the color-filter substrate 306 contains the pixel matrix 308 and color film 310 containing, for example, three primary color (e.g., red, green and blue) dyes or pigments. The dyes, pigments, or inks which make up the color film RGB portion of the color filter, are referred to as color material herein. Between the blocks of color material in the color filter is the pixel matrix. The flat panel display system 300 is further composed of a spacer 312, and a sealant 314 for assembling the two substrates' liquid crystals 302 in the cavity between the substrate and polarizing 316 films on the substrates' outer surfaces. The depicted color filter 306 includes the features of the present invention which include an approximately level or co-planar top surface 308′ of the pixel matrix material 306 and top surface 310′ of the color material 310 (e.g., a difference of approximately 0.2 μm or less). Additionally, the color filter 306 has no gaps at the interface 311 of the side walls of the pattern pixel matrix material 312 and the side of the color material 313. Note that in FIG. 3, the color filter is inverted relative to FIG. 2, so that the top surface of the films appears to be on the bottom of the color filter substrate. More details on display systems and methods of making such systems are given in U.S. patent application Ser. No. 11/737,141 Attorney Docket No. 11548 filed on Apr. 19, 2007 entitled “Methods and Apparatus for Inkjetting Spacers in a Flat Panel Display” and is incorporated herein by reference in its entirety for all purposes.

While the present invention has been described primarily with reference to manufacturing color filters for flat panel displays, it will be understood that the present invention may also be applied to the manufacture of OLED displays as well as other display types. Further, the present invention may also be applied to spacer formation, polarizing coatings, and nanoparticle circuit forming.

Accordingly, while the present invention has been disclosed in connection with exemplary embodiments thereof, it should be understood that other embodiments may fall within the spirit and scope of the invention, as defined by the following claims.

The invention claimed is:

1. A method of processing a substrate, the method comprising:
applying a first activation energy to a patterned pixel matrix material on a substrate sufficient to cause the patterned pixel matrix material to attain a first state, wherein the patterned pixel matrix material in the first state includes a minimized change in volume relative to a volume of the patterned pixel matrix material prior to application of the first activation energy and an increased hardness sufficient to withstand inkjetting;
inkjetting a color material onto the substrate; and
applying an additional activation energy to the patterned pixel matrix material sufficient to attain a second state, wherein the patterned pixel matrix material in the second state includes a reduction in the volume of the patterned pixel matrix material and is substantially hardened.

2. The method of claim 1 wherein the first activation energy is less than the additional activation energy.

3. The method of claim 1 wherein an intermediate activation energy is applied to the patterned pixel matrix material after inkjetting the color material but before applying the additional activation energy.

4. The method of claim 3 wherein the intermediate activation energy includes heating the substrate to a temperature less than or about 110° C.

5. The method of claim 3 wherein the intermediate activation energy is applied for a time less than or about 10 minutes.

6. The method of claim 1 wherein the first activation energy includes heating the substrate to a temperature within a range of about 120° C. to 200° C.

7. The method of claim 1 wherein the first activation energy is applied for a time less than or about 5 minutes.

8. The method of claim 1 wherein the additional activation energy includes heating the substrate to a temperature greater than or about 200° C.

9. The method of claim 1 wherein the additional activation energy is applied for a time of about 10 minutes.

10. The method of claim 1 wherein any of the activation energies is achieved by at least one of applying rapid thermal processing, ultraviolet (UV) radiation, infrared (IR) radiation, electron beam radiation, and laser light radiation.

11. The method of claim 1 wherein the application of the first activation energy to the patterned pixel matrix material initiates solvent removal from the patterned pixel matrix material and initiates cross-linking of the patterned pixel matrix material.

12. The method of claim 1 wherein the patterned pixel material includes an additive with a non-polar portion wherein the application of the first activation energy to a surface of the patterned pixel matrix causes the non-polar portion of the additive to orient toward the surface of the patterned pixel material exposed to the first activation energy.

13. The method of claim 2 wherein the application of the intermediate activation energy to the patterned pixel matrix material removes solvents from the patterned pixel matrix material.

14. The method of claim 1 wherein the application of the additional activation energy to the patterned pixel matrix material crosslinks the patterned pixel matrix material.

15. The method of claim 1 wherein the patterned pixel matrix material includes a top surface and the color material includes a top surface such that after the application of the additional activation energy, the top surface of the color material and the top surface of the patterned pixel matrix material are approximately co-planar.

16. The method of claim 1 wherein the patterned pixel matrix material has at least one side surface and the color material has at least one side surface wherein the at least one side surface of the patterned pixel matrix material and the at least one side surface of the color material meet to form at least one interface such that after the application of the additional activation energy the at least one interface does not include a gap.

17. The method of claim 1 wherein the color material includes ink.

18. A method of processing a substrate, the method comprising:
applying a first activation energy to a patterned pixel matrix material on a substrate sufficient to cause the patterned pixel matrix material to attain a first state, wherein the patterned pixel matrix material in the first state is adapted to withstand inkjetting;
inkjetting a color material onto the substrate; and
applying an additional activation energy to the patterned pixel matrix material sufficient to attain a second state, wherein concurrent shrinking of the patterned pixel matrix material and the color material results in a top surface of the patterned pixel matrix material and a top surface of the color material being approximately co-planar.

19. An apparatus comprising:
a substrate;
a patterned pixel matrix material with a top surface, the patterned pixel matrix material formed on the substrate; and
a color material with a top surface, the color material deposited into the patterned pixel matrix material,
wherein the patterned pixel matrix material and the color material are cured such that concurrent shrinking of the patterned pixel matrix material and the color material results in the top surface of the patterned pixel matrix material and the top surface of the color material being approximately co-planar.

20. The apparatus of claim 19 wherein concurrent shrinking of the patterned pixel matrix material and the color material results in the top surfaces of the patterned pixel matrix material and the top surface of the color material being approximately co-planar without use of a leveling agent.

21. An apparatus of claim 19 including a patterned pixel matrix material with at least one side wall surface; a color material with at least one side surface; wherein concurrent shrinking of the patterned pixel matrix material and the color material results in the side surface of the patterned pixel matrix material and the side surface of the color material forming an interface without gaps.

22. The apparatus of claim 19 wherein the color material includes ink.

23. The apparatus of claim 19 wherein the color material is applied by an inkjet process.

24. An apparatus comprising:
a patterned pixel matrix material with a top surface; and
a color material with a top surface,
wherein the top surface of the patterned pixel matrix material and the top surface of the color material are approximately co-planar,
wherein a first activation energy is applied to the patterned pixel matrix prior to an application of the color material,
wherein an additional activation energy is applied concurrently to the patterned pixel matrix material and the color material,
wherein the first application energy is less than the additional activation energy.

25. A system comprising:
a first substrate with a transistor array;
a second substrate having a patterned pixel matrix material with at least one top surface and a color material with at least one top surface wherein the at least one top surface of the patterned pixel matrix material and the at least one top surface of the color material are approximately co-planar;
a sealant for assembling the first substrate and the second substrate;
a spacer separating the first substrate and the second substrate;
a liquid crystal material between the first substrate and the second substrate; and
one or more polarizers adhered to the outside of the first substrate and the second substrate.
